(19) United States
(12) Patent Application Publication
(10) Pub. No.: US 2024/0231234 A1
(43) Pub. Date: Jul. 11, 2024

(54) SEMICONDUCTOR DEVICE MANUFACTURING METHOD, X-RAY DIFFRACTION DEVICE AND SEMICONDUCTOR PATTERN TRANSFER SYSTEM

(71) Applicant: Mitsubishi Electric Corporation, Tokyo (JP)

(72) Inventor: Yasuhiro MATSUO, Tokyo (JP)

(73) Assignee: Mitsubishi Electric Corporation, Tokyo (JP)

(21) Appl. No.: 18/480,249

(22) Filed: Oct. 3, 2023

(30) Foreign Application Priority Data
Jan. 5, 2023 (JP) 2023-000369

(51) Int. Cl. G03F 7/20; H01L 21/027; H01L 21/67; H01L 21/68; H01L 23/544

(52) U.S. Cl. CPC G03F 7/2039; H01L 21/0274; H01L 21/67282; H01L 21/681; H01L 23/544; H01L 2223/54426; H01L 2223/54493

(57) ABSTRACT

There is provided a semiconductor device manufacturing method which includes: a step of radiating an X-ray to a semiconductor wafer on which two alignment marks are formed and then detecting an intensity of a diffracted X-ray of the X-ray coming from the semiconductor wafer, to thereby determine a direction of a predetermined crystal plane of the semiconductor device, viewed from a direction perpendicular to a surface of the semiconductor wafer; a step of calculating an angle θ created between the direction of the predetermined crystal plane and a straight line connecting these two alignment marks; a step of adjusting a position of the semiconductor wafer so that an angle created between a predetermined reference direction and the straight line is matched with the angle θ; and a step of transferring a pattern onto the semiconductor wafer with reference to the predetermined reference direction.

### BACKGROUND OF THE INVENTION

### 1. Field of the Invention

The present disclosure relates to a semi-conductor device manufacturing method, an X-ray diffraction device and a semiconductor pattern transfer system.

### 2. Description of the Background Art

In conventional semiconductor device manufacturing processes, an alignment mark on a semiconductor wafer is formed with reference to the orientation flat or the notch of the semiconductor wafer. Using the alignment mark as a reference, a pattern is transferred onto the semiconductor wafer. Since the orientation flat or the notch is formed in alignment with the direction of a crystal plane of the semi-conductor wafer, the pattern is transferred to be aligned with such a crystal plane direction.

According to conventional pattern forming methods, however, there are cases where the thus-formed pattern is misaligned with the crystal plane direction. This is because, in some cases, the orientation flat or the notch may be formed in misalignment with the crystal plane direction. In the manufacturing process of a semiconductor laser or the like, there are cases where the semiconductor wafer is divided by cleavage into multiple bars. If the pattern is misaligned with the crystal plane direction, the direction for division by cleavage is misaligned with the pattern.

As a method of suppressing misalignment between the pattern and the crystal plane direction, in Patent Document 1, such a method is disclosed that uses an exposure device employing X-ray diffraction. According to this method using such an exposure device, a semiconductor wafer is subjected to position adjustment using a diffracted X-ray resulting from irradiation of the semiconductor wafer with an X-ray, and then the semiconductor wafer is transported, while its position-adjusted state is being maintained, in the exposure device, and thereafter pattern transfer is executed.
Patent Document 1: Japanese Patent Application Laid-open No. 2003-309056

However, in the case where the exposure device disclosed in Patent Document 1 is used, since a step of transporting the semiconductor wafer while maintaining the position-adjusted state is required, a possibility may arise that the thus-adjusted position is displaced during the transportation so that the transferred pattern is misaligned with the crystal plane direction.

### SUMMARY OF THE INVENTION

The present disclosure has been made to solve the above problem and an object thereof is to provide a semiconductor device manufacturing method, an X-ray diffraction device and a semiconductor pattern transfer system, which can reduce misalignment of the transferred pattern from the crystal plane direction.

A first semiconductor device manufacturing method according to this disclosure comprises: a step of radiating an X-ray to a semiconductor wafer on which two alignment marks are formed and then detecting an intensity of a diffracted X-ray of said X-ray coming from the semiconductor wafer, to thereby determine a direction of a predetermined crystal plane of the semi-conductor wafer, viewed from a direction perpendicular to a surface of the semiconductor wafer; a step of calculating an angle θ created between the direction of the predetermined crystal plane and a straight line connecting said two alignment marks; a step of adjusting a position of the semiconductor wafer so that an angle created between a predetermined reference direction and the straight line is matched with the angle θ; and a step of transferring a pattern onto the semiconductor wafer with reference to the predetermined reference direction.

A second semiconductor device manufacturing method according to this disclosure comprises: a step of radiating an X-ray to a semiconductor wafer and then detecting an intensity of a diffracted X-ray of said X-ray coming from the semiconductor wafer, to thereby determine a direction of a predetermined crystal plane of the semiconductor wafer, viewed from a direction perpendicular to a surface of the semiconductor wafer;
a step of forming two alignment marks so that an angle created between the direction of the predetermined crystal plane and a straight line connecting said two alignment marks is set to an angle ϕ; a step of adjusting a position of the semiconductor wafer so that an angle created between a predetermined reference direction and the straight line is matched with the angle ϕ, and a step of transferring a pattern onto the semiconductor wafer with reference to the predetermined reference direction.

A first X-ray diffraction device according to this disclosure comprises: an X-ray source that radiates an X-ray to a semiconductor wafer on which two alignment marks are formed; an X-ray detector that detects an intensity of a diffracted X-ray of said X-ray coming from the semiconductor wafer; and a control unit that causes the X-ray source to radiate the X-ray and the X-ray detector to detect the intensity of the diffracted X-ray, to thereby determine a direction of a predetermined crystal plane of the semiconductor wafer, viewed from a direction perpendicular to a surface of the semiconductor wafer, and then calculates an angle θ created between the direction of the predetermined crystal plane and a straight line connecting said two alignment marks.

A first semiconductor pattern transfer system according to this disclosure comprises the foregoing first X-ray diffraction device, and a transfer unit that executes: adjusting a position of the semiconductor wafer so that an angle created between a predetermined reference direction and the straight line is matched with the angle θ; and transferring a pattern onto the semiconductor wafer with reference to the predetermined reference direction.

A second X-ray diffraction device according to this disclosure comprises: an X-ray source that radiates an X-ray to a semiconductor wafer; an X-ray detector that detects an intensity of a diffracted X-ray of said X-ray coming from the semiconductor wafer;
a mark former that forms an alignment mark on the semiconductor wafer; and a control unit that causes the X-ray source to radiate the X-ray and the X-ray detector to detect the intensity of the diffracted X-ray, to thereby determine a direction of a predetermined crystal plane of the semiconductor wafer, viewed from a direction perpendicular to a surface of the semi-conductor wafer; and that causes the mark former to form two alignment marks on the semiconductor wafer so that an angle created between the direction of the predetermined crystal plane and a straight line connecting said two alignment marks is set to a predetermined angle ϕ.

A second semiconductor pattern transfer system according to this disclosure comprises the foregoing second X-ray diffraction device, and a transfer unit that executes: adjusting a position of the semiconductor wafer so that an angle created between a predetermined reference direction and the straight line is matched with the angle ϕ; and transferring a pattern onto the semiconductor wafer with reference to the predetermined reference direction.

According to this disclosure, it is possible to provide a semiconductor device manufacturing method, an X-ray diffraction device and a semiconductor pattern transfer system, which can reduce misalignment of the transferred pattern from the crystal plane direction.

### BRIEF DESCRIPTION OF THE DRAWINGS

FIG. 1 is a schematic view of a semiconductor pattern transfer system according to Embodiment 1.

FIG. 2 is a schematic view of an X-ray diffraction device according to Embodiment 1.

FIG. 3 is a schematic view of an exposure device according to Embodiment 1.

FIG. 4 is a top view of a wafer stage and a semiconductor wafer, for illustrating a semiconductor device manufacturing method according to Embodiment 1.

FIG. 5 is a top view of the wafer stage and the semiconductor wafer, for illustrating the semiconductor device manufacturing method according to Embodiment 1.

FIG. 6 is a top view of the wafer stage and the semiconductor wafer, for illustrating the semiconductor device manufacturing method according to Embodiment 1.

FIG. 7 is a top view of an exposure-device wafer stage and the semiconductor wafer, for illustrating the semiconductor device manufacturing method according to Embodiment 1.

FIG. 8 is a schematic view of an X-ray diffraction device according to Embodiment 2.

FIG. 9 is a schematic view of an X-ray diffraction device according to Embodiment 3.

FIG. 10 is a top view of a wafer stage and semiconductor wafer, for illustrating a semiconductor device manufacturing method according to Embodiment 3.

FIG. 11 is a top view of an exposure-device wafer stage and the semiconductor wafer, for illustrating the semiconductor device manufacturing method according to Embodiment 3.

FIG. 12 is a flowchart for illustrating the semiconductor device manufacturing method according to Embodiment 1.

FIG. 13 is a flowchart for illustrating the semiconductor device manufacturing method according to Embodiment 3.

FIG. 14 is a block diagram showing an exemplary hardware configuration for executing the function of a control unit in the X-ray diffraction device and the semiconductor device manufacturing method, according to each of Embodiments in this application.

### DETAILED DESCRIPTION OF THE EMBODIMENTS OF THE INVENTION

### Embodiment 1

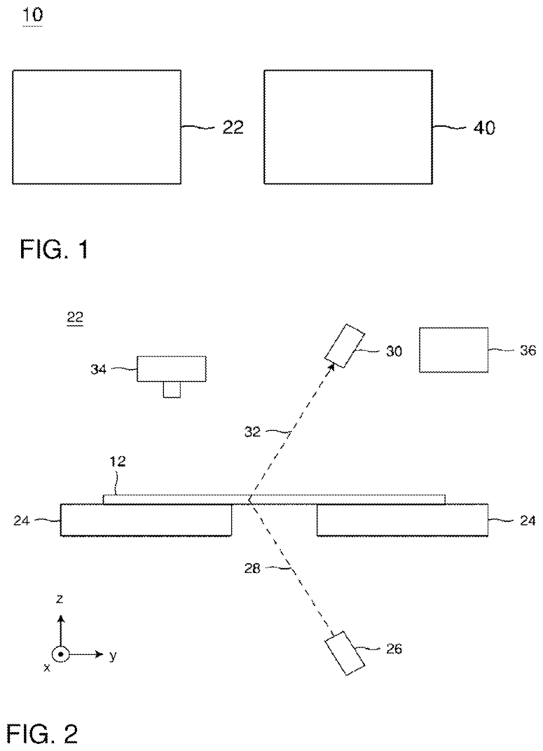

A configuration of a semiconductor pattern transfer system 10 according to Embodiment 1 is shown in FIG. 1. The semiconductor pattern transfer system 10 includes an X-ray diffraction device 22 and an exposure device 40.

The X-ray diffraction device 22 is detailed in FIG. 2. The X-ray diffraction device 22 includes a wafer stage 24, an X-ray source 26, an X-ray detector 30, a camera 34 and a control unit 36. The wafer stage 24 has a chuck function for fixing a semiconductor wafer 12. Further, the wafer stage 24 has a function of moving in x- and y-directions and a function of rotating as viewed from a z-direction. The x- and y-directions are mutually perpendicular directions along the surface of the semiconductor wafer 12, and the z-direction is a direction perpendicular to the surface of the semiconductor wafer 12. The X-ray source 26 serves to radiate an X-ray, which is, for example, an X-ray tube.

The X-ray source 26 radiates an X-ray 28 to the semiconductor wafer 12 from its back side. In the wafer stage 24, an opening is created that causes the X-ray 28 to pass therethrough. The X-ray detector 30 serves to detect an intensity of X-ray, which is, for example, a scintillation counter. The X-ray detector 30 detects an intensity of a diffracted X-ray 32 diffracted by the semiconductor wafer 12. The camera 34 recognizes alignment marks formed on the semiconductor wafer 12. The control unit 36 is connected by wire (not illustrated) or wirelessly to the wafer stage 24, the X-ray source 26, the X-ray detector 30 and the camera 34, and serves to transmit an instruction and to receive the detection result.

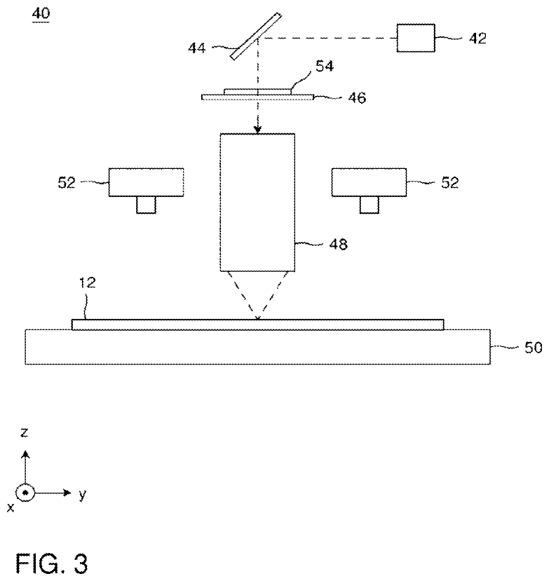

The exposure device 40 is detailed in FIG. 3. The exposure device 40 is a transfer unit that transfers a pattern onto the semiconductor wafer 12. The exposure device 40 includes a light source 42, a mirror 44, a reticle stage 46, a projection lens 48, an exposure-device wafer stage 50 and exposure-device cameras 52. The light source 42 is, for example, composed of a high-pressure mercury lamp, which emits light for transfer. The mirror 44 reflects light from the light source 42. The reticle stage 46 can mount a reticle 54 and is rotatable as viewed from the z-direction. The projection lens 48 collects light having passed through the reticle 54 after reflection off the mirror 44, and then projects that light to the semiconductor wafer 12 on which a resist (not illustrated) is applied. The exposure-device wafer stage 50 has a chuck function for fixing the semiconductor wafer 12. Further, the exposure-device wafer stage 50 has a function of moving in the x- and y-directions and a function of rotating as viewed from the z-direction. There are two exposure-device cameras 52, which each recognize the alignment mark formed on the semiconductor wafer 12.

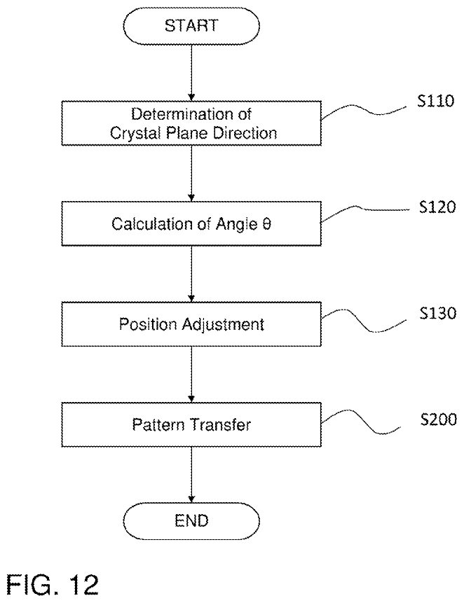

Here, a semiconductor device manufacturing method using the semiconductor pattern transfer system 10 will be described while referring to the flowchart of FIG. 12.

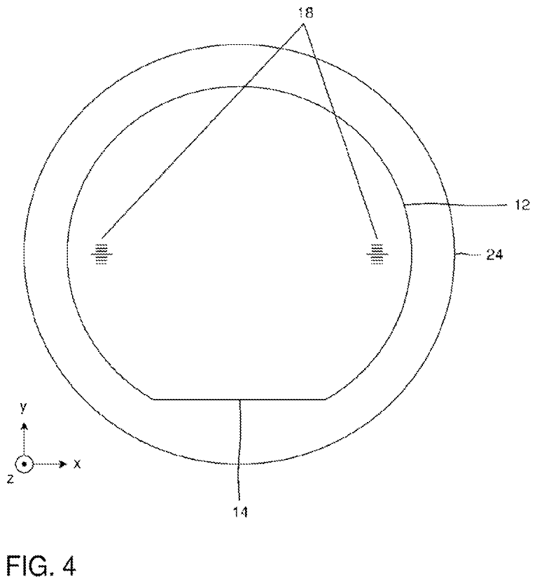

First, as shown in FIG. 4, the semiconductor wafer 12 on which two alignment marks 18 are formed is placed on the wafer stage 24 in the X-ray diffraction device 22. Two alignment marks 18 are being formed in the vicinity of both ends of the semiconductor wafer 12. In the semiconductor wafer 12, an orientation flat 14 along a direction of a predetermined crystal plane is formed. Here, the direction of the predetermined crystal plane is a direction of a predetermined crystal plane of the semiconductor wafer 12 viewed from the z-direction. However, care should be taken that there may be misalignment between the orientation flat 14 and the direction of the predetermined crystal plane. Two alignment marks 18 are being formed so that a straight line connecting these marks is parallel to the orientation flat 14.

Next, a direction 16 of the predetermined crystal plane of the semiconductor wafer 12 is determined (Step S110). First, in response to an instruction by the control unit 36, the X-ray 28 is radiated from the X-ray source 26 to the semiconductor wafer 12 while the wafer stage 24 on which the semiconductor wafer 12 is laid is being rotated. Then, the intensity of the diffracted X-ray 32 of the X-ray 28 coming from the semiconductor wafer 12 is detected by the X-ray detector 30. The X-ray 28 is diffracted by an angle matched with the Bragg reflection condition for the semiconductor wafer 12, and is then detected as the diffracted X-ray 32 by the X-ray detector 30. Accordingly, it is possible to determine the direction 16 of the predetermined plane by investigating the intensity of the diffracted X-ray 32.

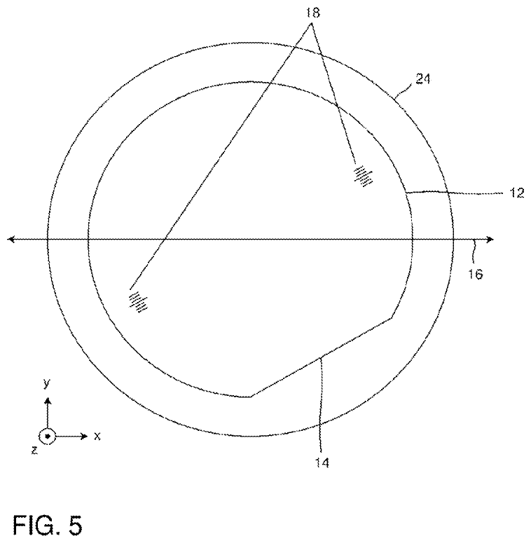

FIG. 5 is a top view of the semiconductor wafer 12 having the predetermined crystal plane whose direction 16 has been determined, and the wafer stage 24. Although it is generally unexpected that the deviation angle between the orientation flat 14 and the direction 16 of the predetermined crystal plane is so large as shown in FIG. 5, for explanation's sake, the deviation angle is overly shown in FIG. 5.

Here, description will be made about a case where the semiconductor wafer is made of InP, as an example. Let's assume that the major plane orientation of the semiconductor wafer is (100), the predetermined crystal plane is the (110) plane and the cleavage plane is the (110) plane. In this case, the direction of the (110) plane is determined by the detection of a (220) peak of a secondary diffracted ray caused by the (110) plane.

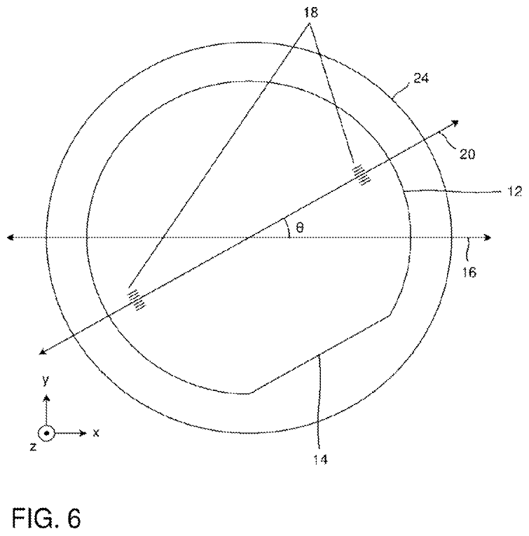

Subsequent to the determination of the direction 16 of the predetermined crystal plane, an angle created between the direction 16 of the pre-determined crystal plane and a straight line 20 connecting two alignment marks 18 is calculated (Step S120). First, in order to determine the straight line 20 connecting two alignment marks 18, the control unit 36 causes the wafer stage 24 to move and/or rotate, to thereby recognize the respective positions of two alignment marks 18 by using the camera 34. Recognition of the positions of two alignment marks 18 makes it possible to determine the straight line 20 connecting these marks. Since the direction 16 of the pre-determined crystal plane has been determined in the previous step, the angle created between the direction 16 of the predetermined crystal plane and the straight line 20 connecting two alignment marks 18 can be calculated by the control unit 36. In the following, this angle is defined as 0. The straight line 20 and the angle θ are indicated in FIG. 6.

Next, the semiconductor wafer 12 is transported and placed on the exposure-device wafer stage 50 in the exposure device 40. A resist (not illustrated) is being applied on the semiconductor wafer 12. Then, the positions of two alignment marks 18 are confirmed using the exposure-device cameras 52. Here, it is assumed that two alignment marks 18 are each confirmed by the operator through manual operation using each of two exposure-device cameras 52. In this case, when the shapes of two alignment marks 18 are each a shape of a scale as shown in FIG. 4, it is easy to visually recognize the misaligned amount. Then, the position of the semiconductor wafer 12 is adjusted through manual operation so that an angle created between a predetermined reference direction 56 and the straight line 20 connecting two alignment marks 18 is matched with the angle θ (Step S130).

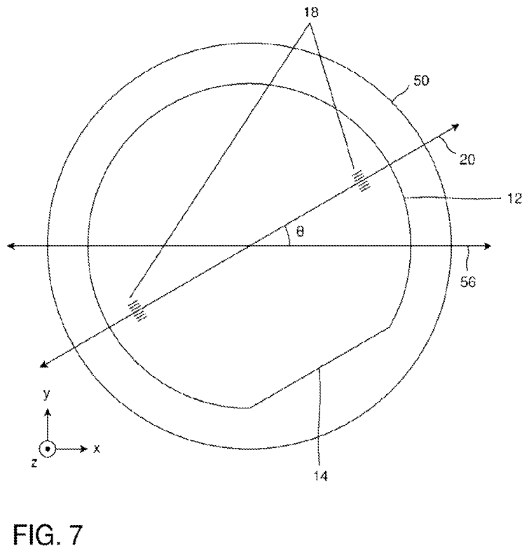

Here, the predetermined reference direction 56 is a direction in which the direction 16 of the predetermined crystal plane of the semiconductor wafer 12 is to be aligned at the time of transferring a pattern in the exposure device 40. Shown in FIG. 7 is a state after the position is adjusted. Note that, in the case of using the exposure-device wafer stage 50 that can move highly accurately, the exposure-device cameras 52 may instead be a single exposure-device camera. Further, the work for adjusting the position may be executed automatically not through manual operation.

Next, using the predetermined reference direction 56 as a reference, a transferring step is applied to the semiconductor wafer 12 to thereby form the pattern (Step S200). On this occasion, the reticle 54 placed on the reticle stage 46 has also been directionally adjusted to be matched with the pre-determined reference direction 56. Since the direction 16 of the predetermined crystal plane and the predetermined reference direction 56 are oriented in the same direction, the pattern is transferred with reference to the direction 16 of the predetermined crystal plane. Accordingly, a semiconductor device with the transferred pattern will be manufactured. This transferring step may be executed multiple times.

As described above, according to this Embodiment, since the direction 16 of the predetermined crystal plane of the semiconductor wafer 12 is determined using a technique of X-ray diffraction and the position of the semiconductor wafer 12 is adjusted on the basis of the angle between the direction 16 of the predetermined crystal angle and the straight line connecting two alignment marks 18, it is possible, even if there is misalignment between the orientation flat 14 and the direction 16 of the predetermined crystal plane, to reduce misalignment of the transferred pattern from the direction of the crystal plane. Further, in the case where cleavage is carried out at a later step, it is possible to reduce misalignment between the cleavage plane and the pattern.

It is noted that two alignment marks 18 may be formed so that a straight line connecting these marks is perpendicular to the direction of the orientation flat 14, or may be formed so that the straight line is oriented in any given direction. Further, the shapes of two alignment marks 18 are not limited to those shown in FIG. 4. Further, instead of the orientation flat 14, a notch may be formed in the semiconductor wafer 12.

### Embodiment 2

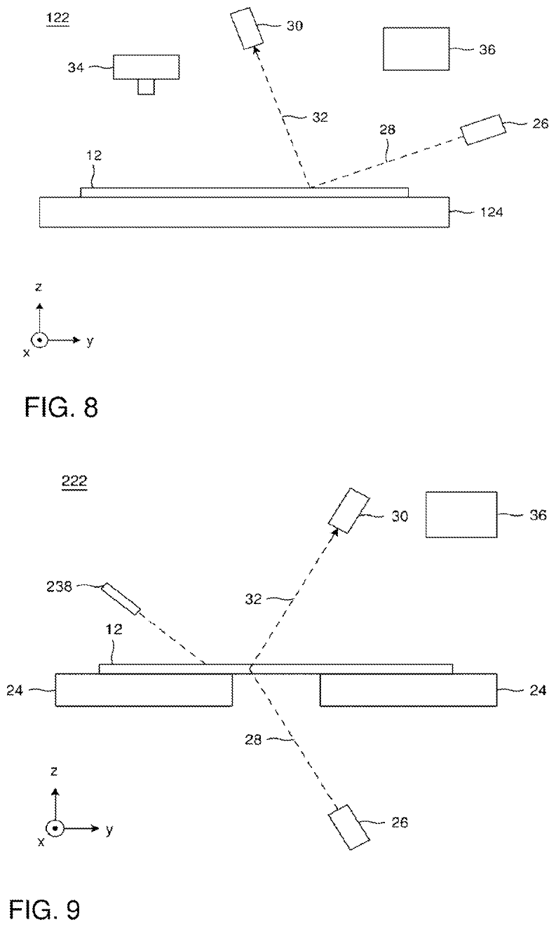

According to Embodiment 2, unlike Embodiment 1, in an X-ray diffraction device 122, the X-ray source 26 radiates the X-ray 28 to the semiconductor wafer 12 from its front side as shown in FIG. 8. In the case where the semiconductor wafer 12 is, for example, made of InP, when the major plane orientation is (100), it is difficult to directly observe the (110) plane that is perpendicular to the major plane. Thus, the direction of the (110) plane is determined using the Bragg reflection condition with respect to a (511) peak that is parallel to or perpendicular to the (110) plane.

According to this Embodiment, since the X-ray source 26 is located on the front side of the semiconductor wafer 12, there is no need to have such a complicated structure in which an opening is created in a wafer stage 124. Thus, it is possible to easily configure the X-ray diffraction device 122.

### Embodiment 3

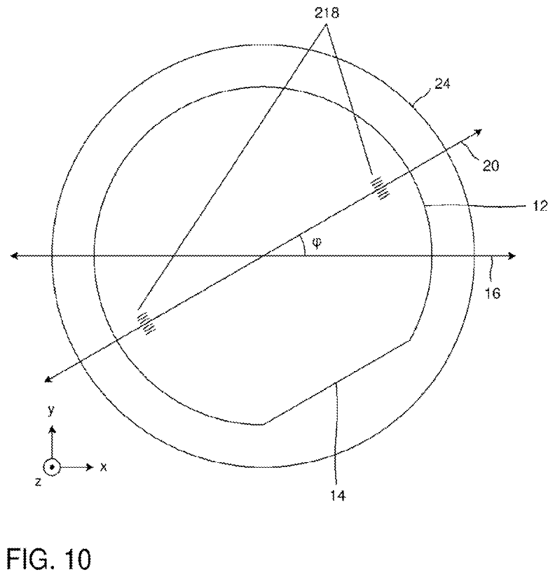

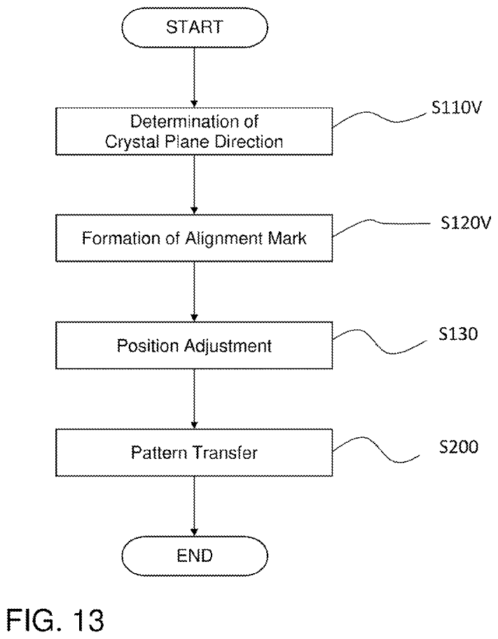

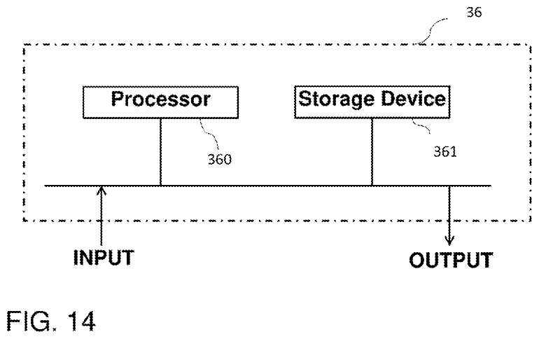

In Embodiment 3, unlike Embodiment 1, an X-ray diffraction device 222 includes a mark former 238 as shown in FIG. 9. The mark former 238 is, for example, a laser marker. Further, no camera is required. According to these differences, as shown in the flowchart of FIG. 13, the manufacturing process is different from the above. In Embodiment 1, two alignment marks 18 are formed beforehand on the semiconductor wafer 12. However, according to this Embodiment, with respect to a semiconductor wafer 12 placed on the wafer stage 24, the determination of the direction 16 of the predetermined crystal plane, based on X-ray diffraction, is firstly executed by the control unit 36 (Step S110V). Then, using the mark former 238, two alignment marks 218 are formed on the semiconductor wafer 12. At this time, as shown in FIG. 10, two alignment marks 218 are formed so that an angle created between the direction 16 of the predetermined crystal plane and the straight line 20 connecting two alignment marks 218 is set to a predetermined angle (hereinafter, referred to as an angle ϕ) (Step S120V).

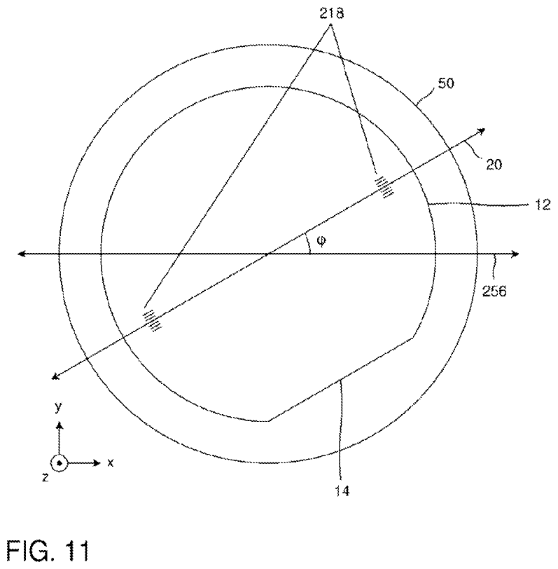

Thereafter, like in Embodiment 1, in the exposure device, a transferring step is applied to the semiconductor wafer 12 to thereby form a pattern. Prior to this step, as shown in FIG. 11, the position of the semiconductor wafer 12 is adjusted so that an angle created between the predetermined reference direction 256 and the straight line 20 connecting two alignment marks 218 is matched with the angle ϕ (Step S130). Then, using the predetermined reference direction 256 as a reference, the transferring step is applied to the semiconductor wafer 12 to thereby form the pattern (Step S200). Since the direction 16 of the predetermined crystal plane and the predetermined reference direction 256 are oriented in the same direction, the pattern is transferred with reference to the direction 16 of the predetermined crystal plane.

According to this Embodiment, for every semiconductor wafer, two alignment marks 218 are formed with reference to the direction 16 of the predetermined crystal plane. Thus, the angle ϕ used for adjusting the position of the semiconductor wafer 12 in the exposure device does not change for every semiconductor wafer. Accordingly, as a value of the angle ϕ, one common value can be used regardless of which one of the wafers is used. Therefore, it is unnecessary to take management actions, such as, storing an angle for position adjustment (corresponding to the angle θ in Embodiment 1) per each semiconductor wafer, and the like.

It is noted that, like in Embodiment 2, the X-ray source may be located on the front side of the semiconductor wafer. Further, the angle ϕ may be zero degree.

It is noted that, as shown in FIG. 14, exemplary hardware of the control unit 36 or an unshown control device for executing the semiconductor device manufacturing method, is configured with a processor 360 and a storage device 361. Although not illustrated, the storage device includes: a volatile storage device such as a random-access memory or the like; and a non-volatile auxiliary storage device such as a flash memory or the like. Further, as the auxiliary storage device, a hard disc drive may be included instead of the flash memory. The processor 360 executes a program inputted from the storage device 361. On this occasion, the program is inputted from the auxiliary storage device to the processor 360 through the volatile storage device. Further, the processor 360 may output data such as a calculation result, etc. to the volatile storage device in the storage device 361, and may store that data in the auxiliary storage device through the volatile storage device. Although the processer 360 may have a communication function, there may be included an unshown separate communication unit.

It should be noted that, in this disclosure, a variety of exemplary embodiments and examples are described; however, every characteristic, configuration or function that is described in one or more embodiments, is not limited to being applied to a specific embodiment, and may be applied singularly or in any of various combinations thereof to another embodiment. Accordingly, an infinite number of modified examples that are not exemplified here are supposed within the technical scope disclosed in this description. For example, such cases shall be included where at least one configuration element is modified; where any configuration element is added or omitted; and furthermore, where at least one configuration element is extracted and combined with a configuration element of another embodiment.

What is claimed is:

1. A semiconductor device manufacturing method, comprising:
a step of radiating an X-ray to a semiconductor wafer on which two alignment marks are formed and then detecting an intensity of a diffracted X-ray of said X-ray coming from the semiconductor wafer, to thereby determine a direction of a predetermined crystal plane of the semiconductor wafer, viewed from a direction perpendicular to a surface of the semiconductor wafer;
a step of calculating an angle θ created between the direction of the predetermined crystal plane and a straight line connecting said two alignment marks;
a step of adjusting a position of the semiconductor wafer so that an angle created between a predetermined reference direction and the straight line is matched with the angle θ, said predetermined reference direction being a direction in which the predetermined crystal plane is to be aligned at a time of transferring a pattern; and
a step of transferring the pattern onto the semi-conductor wafer.

2. A semiconductor device manufacturing method, comprising:
a step of radiating an X-ray to a semiconductor wafer and then detecting an intensity of a diffracted X-ray of said X-ray coming from the semiconductor wafer, to thereby determine a direction of a predetermined crystal plane of the semiconductor wafer, viewed from a direction perpendicular to a surface of the semi-conductor wafer;
a step of forming two alignment marks so that an angle created between the direction of the pre-determined crystal plane and a straight line connecting said two alignment marks is set to an angle ϕ;
a step of adjusting a position of the semiconductor wafer so that an angle created between a predetermined reference direction and the straight line is matched with the angle ϕ, said predetermined reference direction being a direction in which the predetermined crystal plane is to be aligned at a time of transferring a pattern; and
a step of transferring the pattern onto the semi-conductor wafer.

3. An X-ray diffraction device, comprising:
an X-ray source that radiates an X-ray to a semiconductor wafer on which two alignment marks are formed;
an X-ray detector that detects an intensity of a diffracted X-ray of said X-ray coming from the semiconductor wafer; and
a control unit that causes the X-ray source to radiate the X-ray and the X-ray detector to detect the intensity of the diffracted X-ray, to thereby determine a direction of a predetermined crystal plane of the semiconductor wafer, viewed from a direction perpendicular to a surface of the semiconductor wafer, and then calculates an angle θ created between the direction of the predetermined crystal plane and a straight line connecting said two alignment marks.

4. A semiconductor pattern transfer system, comprising:
the X-ray diffraction device as set forth in claim 3; and
a transfer unit that executes: adjusting a position of the semiconductor wafer so that an angle created between a predetermined reference direction and the straight line is matched with the angle θ, said predetermined reference direction being a direction in which the predetermined crystal plane is to be aligned at a time of transferring a pattern; and transferring the pattern onto the semiconductor wafer.

5. An X-ray diffraction device, comprising:
an X-ray source that radiates an X-ray to a semiconductor wafer;
an X-ray detector that detects an intensity of a diffracted X-ray of said X-ray coming from the semiconductor wafer;
a mark former that forms an alignment mark on the semiconductor wafer; and
a control unit that causes the X-ray source to radiate the X-ray and the X-ray detector to detect the intensity of the diffracted X-ray, to thereby determine a direction of a predetermined crystal plane of the semiconductor wafer, viewed from a direction perpendicular to a surface of the semiconductor wafer; and that causes the mark former to form two alignment marks on the semiconductor wafer so that an angle created between the direction of the predetermined crystal plane and a straight line connecting said two alignment marks is set to a predetermined angle ϕ.

6. A semiconductor pattern transfer system, comprising:
the X-ray diffraction device as set forth in claim 5; and
a transfer unit that executes: adjusting a position of the semiconductor wafer so that an angle created between a predetermined reference direction and the straight line is matched with the angle ϕ, said predetermined reference direction being a direction in which the predetermined crystal plane is to be aligned at a time of transferring a pattern; and transferring the pattern onto the semiconductor wafer.
